(19) United States
(12) Patent Application Publication
(10) Pub. No.: US 2013/0045592 A1
(43) Pub. Date: Feb. 21, 2013

(54) METHOD FOR MANUFACTURING SILICON CARBIDE SEMICONDUCTOR DEVICE AND DEVICE FOR MANUFACTURING SILICON CARBIDE SEMICONDUCTOR DEVICE

(71) Applicants: Tomihito Miyazaki, Osaka-shi (JP); Hiromu Shiomi, Osaka-shi (JP); Hideto Tamaso, Osaka-shi (JP); Takeyoshi Masuda, Osaka-shi (JP)

(72) Inventors: Tomihito Miyazaki, Osaka-shi (JP); Hiromu Shiomi, Osaka-shi (JP); Hideto Tamaso, Osaka-shi (JP); Takeyoshi Masuda, Osaka-shi (JP)

(73) Assignee: SUMITOMO ELECTRIC INDUSTRIES, LTD., Osaka-shi (JP)

(21) Appl. No.: 13/695,775

(22) PCT Filed: Nov. 4, 2011
(86) PCT No.: PCT/JP2011/075395

§ 371 Date: Nov. 1, 2012

(30) Foreign Application Priority Data
Nov. 24, 2010 (JP) 2010-261323

(51) Int. Cl. H01L 21/265; C23C 16/40

(52) U.S. Cl. 438/514; 118/715; 257/E21.335

(57) ABSTRACT

A method for manufacturing a SiC semiconductor device includes: a step of forming an oxide film on a surface of a SiC substrate; and a step of removing the oxide film. In the step of forming the oxide film, ozone gas is used. In the step of removing the oxide film, it is preferable to use halogen plasma or hydrogen plasma. In this way, problems associated with a chemical solution can be reduced while obtaining a method and device for manufacturing a SiC semiconductor device, by each of which a cleaning effect can be improved.

### TECHNICAL FIELD

The present invention relates to a method for manufacturing a silicon carbide (SiC) semiconductor and a device for manufacturing such a SiC semiconductor.

### BACKGROUND ART

SiC has a large band gap, and has a maximum dielectric breakdown electric field and a heat conductivity both larger than those of silicon (Si). In addition, SiC has a carrier mobility as large as that of silicon, and has a large electron saturation drift velocity and a large breakdown voltage. Hence, it is expected to apply SiC to semiconductor devices, which are required to attain high efficiency, high breakdown voltage, and large capacity.

In a method for manufacturing such a SiC semiconductor device, cleaning is performed to remove attached substances from a surface of the SiC semiconductor. An exemplary cleaning method is a technique disclosed in Japanese Patent Laying-Open No. 2001-35838 (Patent Literature 1). Patent Literature 1 discloses that after annealing to activate impurities implanted in a SiC substrate by means of ion implantation, RCA cleaning is performed as a pretreatment method for surface cleaning and then surface etching is performed by means of plasma. Patent Literature 1 also discloses that the RCA cleaning is performed in the following procedure. That is, in order to remove organic substances and noble metals, treatment is performed using sulfuric acid and hydrogen peroxide (H₂SO₄:H₂O₂=4:1), and then diluted HF treatment is performed to remove a natural oxidation film. Thereafter, in order to remove metals existing in the natural oxidation oxide film, treatment is performed using hydrochloric acid and hydrogen peroxide (HCl: H₂O₂:H₂O=1:1:6). Finally, in order to remove a natural oxidation film newly produced during these processes, diluted HF treatment is performed again.

### CITATION LIST

### Patent Literature

PTL 1: Japanese Patent Laying-Open No. 2001-35838

### SUMMARY OF INVENTION

### Technical Problem

Hydrogen peroxide (H₂O₂) used in the RCA cleaning of Patent Literature 1 is an unstable material and is likely to be decomposed. Hence, the surface cannot be cleaned sufficiently by the RCA cleaning using hydrogen peroxide.

Further, when the RCA cleaning is performed, an amount of usage of chemical solution is increased to result in problems with control of concentration of the chemical solution, handling of waste liquid, and the like. Thus, the RCA cleaning involves the problems associated with a chemical solution.

Accordingly, the present invention has its object to provide a method for manufacturing a SiC semiconductor device and a device for manufacturing a SiC semiconductor device, whereby the problems associated with a chemical solution can be reduced while improving a cleaning effect.

### Solution to Problem

A method for manufacturing a SiC semiconductor device in the present invention includes the steps of: forming an oxide film on a surface of SiC; and removing the oxide film, in the step of forming the oxide film, ozone (O₃) gas being used.

According to the method for manufacturing the SiC semiconductor device in the present invention, the oxide film is formed using the ozone gas. The ozone gas has high oxidizing energy (degree of activity), and therefore allows the oxide film to be readily formed on the surface of the SiC semiconductor, which is a stable compound. In this way, the oxide film can be readily formed to incorporate impurities, particles, and the like attached to the surface thereof. By removing this oxide film, the impurities, the particles, and the like incorporated therein can be removed. Accordingly, a cleaning effect can be improved as compared with that of the RCA cleaning.

Further, in the step of forming the oxide film, no chemical solution needs to be used. Accordingly, the problems associated with a chemical solution involved in cleaning can be reduced.

Preferably in the method for manufacturing the SiC semiconductor device, in the step of removing the oxide film, halogen plasma or hydrogen (H) plasma is used.

In this case, also in the step of removing the oxide film, no chemical solution needs to be used. Accordingly, the problems associated with a chemical solution involved in cleaning can be reduced.

When the halogen plasma or the H plasma is employed to remove the oxide film, influence of anisotropy due to the plane orientation of SiC can be reduced. Accordingly, the oxide film formed on the surface of the SiC semiconductor can be removed with the in-plane variation being reduced. Further, because the SiC semiconductor is a stable compound, damages on the SiC semiconductor are small even when the halogen plasma is used. Accordingly, the surface of the SiC semiconductor can be cleaned while maintaining excellent surface properties of the SiC semiconductor.

Preferably in the method for manufacturing the SiC semiconductor device, in the step of removing the oxide film, fluorine (F) plasma is used as the halogen plasma.

The F plasma provides high etching efficiency and low possibility of metal contamination. Hence, the surface of the SiC semiconductor can be cleaned to achieve more excellent surface properties.

Preferably in the method for manufacturing the SiC semiconductor device, the step of removing the oxide film is performed at a temperature of not less than 20° C. and not more than 400° C. In this way, damages on the SiC semiconductor can be reduced.

Preferably in the method for manufacturing the SiC semiconductor device, the step of removing the oxide film is performed at a pressure of not less than 0.1 Pa and not more than 20 Pa.

In this way, reactivity between the halogen plasma or the H plasma and the oxide film can be improved, thereby facilitating removal of the oxide film.

In the method for manufacturing the SiC semiconductor device, in the step of removing the oxide film, hydrogen fluoride (HF) may be used. Also when HF is used, the oxide film can be readily removed.

Preferably, the method for manufacturing the SiC semiconductor device further includes the step of performing, between the step of forming the oxide film and the step of removing the oxide film, heat treatment to the SiC semiconductor in an atmosphere including an inert gas.

When performing the step of forming the oxide film, carbon (C) may be deposited on the surface. However, by performing the heat treatment after forming the oxide film, carbon on the surface can be distributed in the SiC semiconductor. Accordingly, a surface close to a stoichiometric composition can be formed.

Preferably, the method for manufacturing the SiC semiconductor device further includes the step of implanting, prior to the step of forming the oxide film, at least one of an inert gas ion and a hydrogen ion into the surface of the SiC semiconductor.

Accordingly, by the ion implantation of the at least one of the inert gas ion and the hydrogen ion, crystal defects can be introduced in the vicinity of the surface. In the step of forming the oxide film, active oxygen from the ozone gas is supplied via the crystal defects. Accordingly, the oxide film can be readily formed in the range in which the crystal defects have been introduced. Accordingly, the cleaning effect can be improved more.

Preferably in the method for manufacturing the SiC semiconductor device, in the step of forming the oxide film, the SiC semiconductor is heated to not less than 20° C. and not more than 600° C.

By heating to not less than 20° C., a rate of oxidation reaction between surface 1a and ozone gas can be increased. Hence, the oxide film can be formed more readily. By heating to not more than 600° C., decomposition of the ozone gas can be restrained. Accordingly, the oxide film can be more readily formed.

Preferably in the method for manufacturing the SiC semiconductor device, the step of forming the oxide film is performed at a pressure of not less than 0.1 Pa and not more than 50 Pa. Accordingly, the oxide film can be more readily formed.

Preferably in the method for manufacturing the SiC semiconductor device, the step of forming the oxide film is performed in an atmosphere including at least one selected from a group consisting of nitrogen, argon, helium, carbon dioxide, and carbon monoxide.

Accordingly, the ozone gas can be effectively restrained from being decomposed, thereby further facilitating formation of the oxide film.

A device for manufacturing a SiC semiconductor device in one aspect of the present invention includes a forming unit, a removing unit, and a connection unit. The forming unit forms an oxide film on a surface of a SiC semiconductor. The removing unit removes the oxide film using ozone gas. The connection unit connects the forming unit and the removing unit to each other to allow the SiC semiconductor to be transported therein. The connection unit has a region in which the SiC semiconductor is transported and which is capable of being isolated from ambient air.

A device for manufacturing a SiC semiconductor device in another aspect of the present invention includes: a forming unit for forming an oxide film on a surface of a SiC semiconductor using ozone gas; and a removing unit for removing the oxide film, the forming unit and the removing unit being the same component.

According to the device for manufacturing the SiC semiconductor device in each of the one and another aspects of the present invention, the SiC semiconductor can be restrained from being exposed to the ambient air while forming the oxide film on the surface of the SiC semiconductor using the forming unit and thereafter removing the oxide film using the removing unit. In this way, impurities in the ambient air can be restrained from attaching to the surface of the SiC semiconductor again. Further, because the oxide film is formed using ozone gas having a high degree of activity, the oxide film can be readily formed. Accordingly, the cleaning effect can be improved as compared with that of the RCA cleaning.

Further, in the forming unit, the oxide film can be formed without using a chemical solution. Accordingly, the problems associated with a chemical solution involved in cleaning can be reduced.

### Advantageous Effects of Invention

As described above, according to the method and device for manufacturing the SiC semiconductor device in the present invention, the problems associated with a chemical solution can be reduced while achieving improved cleaning effect.

### BRIEF DESCRIPTION OF DRAWINGS

FIG. 1 is a schematic view of a manufacturing device for a SiC semiconductor device in a first embodiment of the present invention.

FIG. 2 is a flowchart showing the method for manufacturing the SiC semiconductor device in the first embodiment of the present invention.

FIG. 3 is a cross sectional view schematically showing a SiC substrate serving as a SiC semiconductor and prepared in the first embodiment of the present invention.

FIG. 4 is a cross sectional view schematically showing a state in which an oxide film is formed on the SiC substrate in the first embodiment of the present invention.

FIG. 5 is a cross sectional view schematically showing a state in which the oxide film is removed in the first embodiment of the present invention.

FIG. 6 is a cross sectional view schematically showing a state in which an epitaxial layer is formed on the SiC substrate in the first embodiment of the present invention.

FIG. 7 is a cross sectional view schematically showing an epitaxial wafer serving as the SiC semiconductor and cleaned in the first embodiment of the present invention.

FIG. 8 is a cross sectional view schematically showing a state in which an oxide film is formed on the epitaxial wafer in the first embodiment of the present invention.

FIG. 9 is a cross sectional view schematically showing a state in which the oxide film is removed in the first embodiment of the present invention.

FIG. 10 is a cross sectional view schematically showing a state in which an insulating film to constitute the SiC semiconductor device is formed on the epitaxial wafer in the first embodiment of the present invention.

FIG. 11 is a cross sectional view schematically showing a state in which source electrodes are formed in the first embodiment of the present invention.

FIG. 12 is a cross sectional view schematically showing a state in which source electrodes are formed in the first embodiment of the present invention.

FIG. 13 is a cross sectional view schematically showing a state in which an oxide film is formed on the backside surface of the SiC substrate in the first embodiment of the present invention.

FIG. 14 is a cross sectional view schematically showing a state in which the oxide film is removed and electrodes are formed in the first embodiment of the present invention.

FIG. 15 is a cross sectional view schematically showing a state in which a gate electrode is formed in the first embodiment of the present invention.

FIG. 16 is a schematic view of a manufacturing device for a SiC semiconductor device in a second embodiment of the present invention.

FIG. 17 is a cross sectional view schematically showing an epitaxial wafer to be cleaned in an Example.

### DESCRIPTION OF EMBODIMENTS

The following describes embodiments of the present invention with reference to figures. It should be noted that in the below-mentioned figures, the same or corresponding portions are given the same reference characters and are not described repeatedly.

### First Embodiment

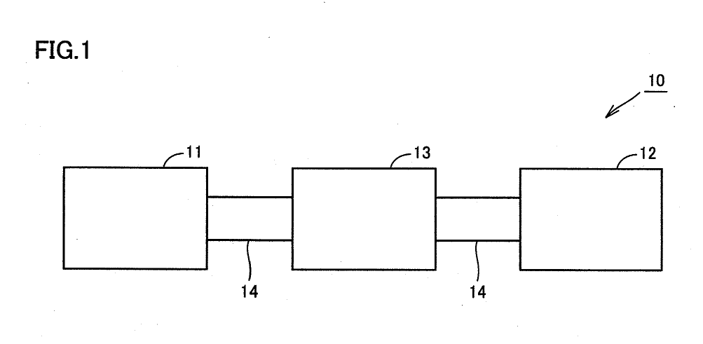

FIG. 1 is a schematic view of a manufacturing device 10 for a SiC semiconductor device in a first embodiment of the present invention. Referring to FIG. 1, the following describes manufacturing device 10 for a SiC semiconductor device in one embodiment of the present invention.

As shown in FIG. 1, manufacturing device 10 for a SiC semiconductor device includes a forming unit 11, a removing unit 12, a heat treatment unit 13, and a connection unit 14. Forming unit 11, removing unit 12, and heat treatment unit 13 are connected to one another by connection unit 14. Respective insides of forming unit 11, removing unit 12, heat treatment unit 13, and connection unit 14 are isolated from ambient air and can be communicated with one another.

Forming unit 11 employs ozone gas to form an oxide film on a surface of a SiC semiconductor. An exemplary forming unit 11 is a device for forming an oxide film using an ozone gas generating device.

Removing unit 12 removes the oxide film formed by forming unit 11. Examples of removing unit 12 include: a plasma generating device; a device for removing an oxide film using a solution, such as HF, capable of reducing the oxide film; a heat decomposing device; and the like. Preferably, removing unit 12 employs halogen plasma or H plasma to remove the oxide film. As the halogen plasma, it is more preferable to use fluorine plasma to remove the oxide film.

In the case where removing unit 12 is a plasma generating device, the following device can be used, for example: a parallel plate type RIE (Reactive Ion Etching) device; an ICP (Inductive Coupled Plasma) type RIE device; an ECR (Electron Cyclotron Resonance) type ME device; an SWP (Surface Wave Plasma) type RIE device; a CVD (Chemical Vapor Deposition) device; or the like.

Heat treatment unit 13 is disposed between forming unit 11 and removing unit 12, and performs heat treatment to the SiC semiconductor in an atmosphere including an inert gas.

Connection unit 14 connects forming unit 11 and removing unit 12 to each other to allow the SiC semiconductor to be transported therein. In the present embodiment, connection unit 14 is disposed between forming unit 11 and heat treatment unit 13, and between heat treatment unit 13 and removing unit 12. Connection unit 14 has a region (internal space) in which the SiC semiconductor is transported. The region can be isolated from the ambient air.

Here, the expression “isolation from the ambient air” (atmosphere isolated from the ambient air) is intended to indicate an atmosphere in which no ambient air is mixed. An example of such an atmosphere is a vacuum or an atmosphere composed of inert gas or nitrogen gas. A specific example of the atmosphere isolated from the ambient air is: vacuum; or an atmosphere filled with nitrogen (N), helium (He), neon (Ne), argon (Ar), krypton (Kr), xenon (Xe), radon (Rn), or a gas composed of a combination thereof.

In the present embodiment, connection unit 14 connects the inside of forming unit 11 and the inside of heat treatment unit 13 to each other, and connects the inside of heat treatment unit 13 and the inside of removing unit 12 to each other. It should be noted that connection unit 14 of the present invention may connect the inside of forming unit 11 and the inside of removing unit 12 to each other. In other word, connection unit 14 may have its inside provided with a space for transporting a SiC semiconductor from forming unit 11 to removing unit 12. Connection unit 14 is installed to transport the SiC semiconductor from forming unit 11 to removing unit 12 without exposing the SiC semiconductor to the ambient air.

Connection unit 14 is dimensioned to allow the SiC semiconductor to be transported therein. Further, connection unit 14 may be dimensioned such that a SiC semiconductor placed on a susceptor can be transported therein. Examples of connection unit 14 include: a load lock chamber connecting the outlet of forming unit 11 and the inlet of heat treatment unit 13 to each other; and a load lock chamber connecting the outlet of heat treatment unit 13 and the inlet of removing unit 12 to each other.

Further, manufacturing device 10 may further include a first transporting unit, disposed in connection unit 14, for transporting a SiC semiconductor from forming unit 11 to removing unit 12. Manufacturing device 10 may further include a second transporting unit for letting out, from manufacturing device 10, a SiC semiconductor from which an oxide film has been removed by removing unit 12, or for transporting a SiC semiconductor to an oxide film forming unit in an atmosphere isolated from the ambient air, so as to form an oxide film to constitute a SiC semiconductor device. The first transporting unit and the second transporting unit may be the same or different.

Further, manufacturing device 10 may further include: a vacuum pump for exhausting the internal atmospheric gas; or a replacing gas container for replacing the internal atmospheric gas. The vacuum pump or the replacing gas container may be connected to each of or at least one of forming unit 11, removing unit 12, and connection unit 14.

It should be noted that manufacturing device 10 may include various elements other than those described above, but for ease of description, these elements are not described and are not shown in figures.

Although FIG. 1 illustrates the configuration in which connection unit 14 connects forming unit 11 and removing unit 12 to each other, the present invention is not particularly limited to this. As connection unit 14, a chamber isolated from the ambient air can be used, for example. In this chamber, forming unit 11 and removing unit 12 may be disposed.

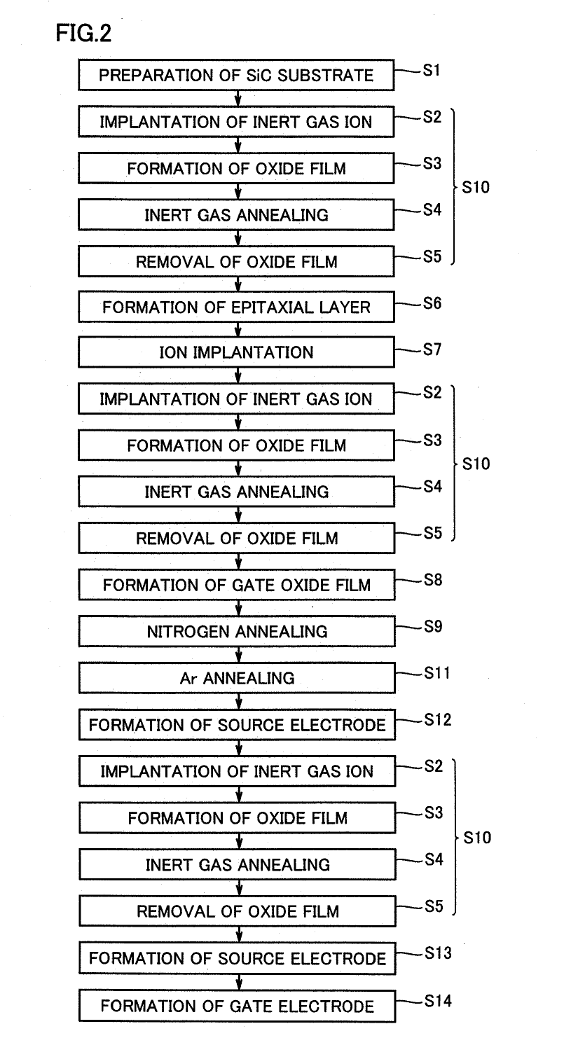

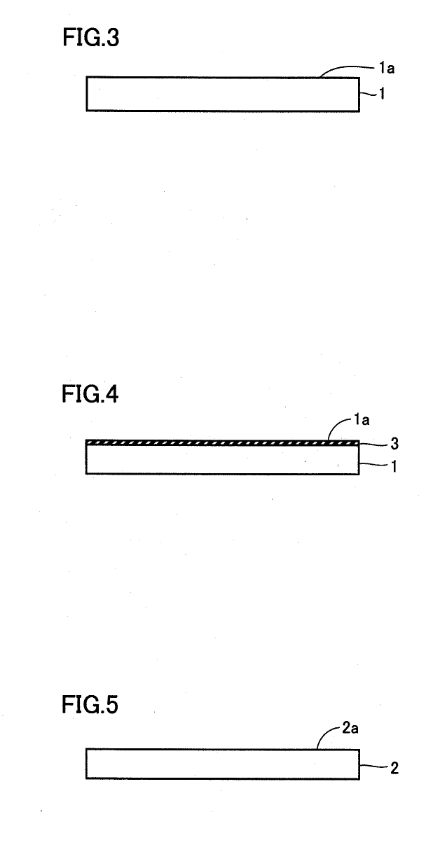

FIG. 2 is a flowchart showing a method for manufacturing a SiC semiconductor device in the present embodiment. FIG. 3 to FIG. 15 are cross sectional views schematically showing respective steps in manufacturing the SiC semiconductor device in the present embodiment. Referring to FIG. 1 to FIG. 15, the following describes the method for manufacturing the SiC semiconductor device in one embodiment of the present invention. In the present embodiment, a method for manufacturing a vertical type MOSFET as the SiC semiconductor device is illustrated. Further, in the present embodiment, manufacturing device 10 for the SiC semiconductor in FIG. 1 is used.

As shown in FIG. 2 and FIG. 3, a SiC substrate 1 having a surface 1a is prepared (step S1). SiC substrate 1 is not particularly limited and can be prepared by, for example, the following method.

Specifically, for example, a SiC ingot is prepared which is grown by means of: a vapor phase epitaxy method such as an HVPE (Hydride Vapor Phase Epitaxy) method, an MBE (Molecular Beam Epitaxy) method, an OMVPE (OrganoMetallic Vapor Phase Epitaxy) method, a sublimation method, or a CVD method; or a liquid phase epitaxy method such as a flux method or a high nitrogen pressure solution method. Thereafter, the SiC ingot is cut to obtain a SiC substrate having surfaces. A method of cutting is not particularly limited. The SiC substrate can be obtained by slicing the SiC ingot. Next, a surface of the SiC substrate thus obtained by cutting is polished. The surface to be polished may be only the front-side surface or both the front-side surface and a backside surface opposite thereto. A method of polishing is not particularly limited. For example, a CMP (chemical mechanical polishing) is employed to planarize the surface and reduce damages such a scratches. The CMP employs colloidal silica as a polishing agent, employs diamond or chrome oxide as abrasive grains, and employs an adhesive agent, wax, or the like as a fixing agent. It should be noted that in addition to or instead of the CMP, other polishing may be performed such as an electric field polishing method, a chemical polishing method, or a mechanical polishing method. Alternatively, the polishing may not be performed. In this way, SiC substrate 1 can be prepared which has surface 1a shown in FIG. 3. An exemplary SiC substrate 1 used herein is a substrate having n type conductivity and having a resistance of 0.02 Ωcm.

Next, as shown in FIG. 2, surface 1a of SiC substrate 1 is cleaned (steps S2 to S5; S10). A method of cleaning is performed as follows, for example.

Specifically, as shown in FIG. 2, at least one of an inert gas ion and a hydrogen ion (H⁺) is implanted into surface 1a of SiC substrate 1 (step S2). The inert gas ion is a helium ion (He⁺), a neon ion (Ne⁺), an argon ion (Ar⁺), a krypton ion (Kr⁺), a xenon ion (Xe⁺), a radon ion (Rn⁺), or a combination thereof.

In step S2, a region to have an oxide film formed thereon in the below-described step S3 is subjected to ion implantation. In the present embodiment, the entire surface 1a of SiC substrate 1 is subjected to the ion implantation.

Next, as shown in FIG. 2 and FIG. 4, an oxide film 3 is formed on surface 1a of SiC substrate 1 using ozone gas (step S3). In step S2 of the present embodiment, oxide film 3 is formed by forming unit 11 of manufacturing device 10 in FIG. 1.

In this step S3, it is preferable to heat the SiC semiconductor to not less than 20° C. and not more than 600° C. By heating to not less than 20° C., a rate of oxidation reaction between surface 1a and the ozone gas can be increased. By heating to not more than 600° C., decomposition of the ozone gas can be restrained.

Further, in this step S3, it is preferable to supply the ozone gas at a pressure of not less than 0.1 Pa and not more than 50 Pa. By supplying it at not less than 0.1 Pa, decomposition of the ozone gas can be restrained. By supplying it at not more than 50 Pa, the rate of oxidation reaction between surface 1a and the ozone gas can be increased.

Further, it is preferable to perform this step S3 in an atmosphere including at least one selected from a group consisting of nitrogen, argon, helium, carbon dioxide, and carbon monoxide. In this way, decomposition of the ozone gas can be restrained.

Further, in this step S3, it is preferable to set partial pressure (concentration) of the ozone gas at not less than 2% and not more than 90%. By setting it at not less than 2%, the rate of oxidation reaction between surface 1a and the ozone gas can be increased. By setting it at not more than 90%, decomposition of the ozone gas can be restrained.

In this step S3, for example, oxide film 3 is formed to have a thickness of not less than one molecular layer and not more than 30 nm. By forming oxide film 3 to have a thickness of not less than one molecular layer, impurities, particles, and the like on surface 1a can be incorporated into the oxide film. By forming oxide film 3 to have a thickness of not more than 30 nm, oxide film 3 will be readily removed in step S5 described below.

By performing this step S3, particles, metal impurities, and the like attached to surface 1a of SiC substrate 1 can be incorporated into surface and inside of oxide film 3. It should be noted that oxide film 3 is, for example, a silicon oxide.

Next, referring to FIG. 1, SiC substrate 1 thus having oxide film 3 formed thereon by forming unit 11 is transported to heat treatment unit 13 via connection unit 14. In doing so, SiC substrate 1 is transported in connection unit 14 having an atmosphere isolated from the ambient air. In other words, between step S2 of forming oxide film 3 and the below-described step S4 of performing inert gas annealing, SiC substrate 1 is in an atmosphere isolated from the ambient air. In this way, after forming oxide film 3, impurities in the ambient air can be restrained from attaching to SiC substrate 1.

Next, in an atmosphere including an inert gas, SiC substrate 1 is subjected to heat treatment (step S4). It is preferable to perform the heat treatment in an atmosphere containing argon. Further, it is preferable to perform the heat treatment at not less than 1300° C. and not more than 1500° C.

In step S3 of forming oxide film 3, carbon may be deposited on surface 1a to result in point defects, but by performing this step S4 to provide the heat treatment to surface 1a of SiC substrate 1, the carbon on surface 1a can be distributed in SiC substrate 1. Accordingly, when performing step S5 to remove oxide film 3 as described below, a surface close to the stoichiometric composition can be formed.

Next, referring to FIG. 1, SiC substrate 1 having oxide film 3 formed thereon by forming unit 11 is transported to removing unit 12 via connection unit 14. In doing so, SiC substrate 1 is transported in connection unit 14 having an atmosphere isolated from the ambient air. In other words, between step S4 of performing inert gas annealing and step S5 of removing oxide film 3, SiC substrate 1 is in an atmosphere isolated from the ambient air. In other words, between step S3 of forming oxide film 3 and step S5 of removing oxide film 3, SiC substrate 1 is in an atmosphere isolated from the ambient air. In this way, after forming oxide film 3, impurities in the ambient air can be restrained from attaching to SiC substrate 1.

Next, as shown in FIG. 3 and FIG. 5, oxide film 3 is removed (step S5). In step S5 of the present embodiment, oxide film 3 is removed using removing unit 12 of manufacturing device 10 shown in FIG. 1.

A method of removing oxide film 3 is not particularly limited. For example, halogen plasma, H plasma, thermal decomposition, dry etching, wet etching, and the like can be used.

The halogen plasma refers to plasma generated from a gas including a halogen element. Examples of the halogen element include fluorine (F), chlorine (Cl), bromine (Br), and iodine (I). An expression “oxide film 3 is removed using halogen plasma” is intended to indicate that oxide film 3 is etched using a plasma that employs a gas including the halogen element. In other words, it is intended to indicate that oxide film 3 is processed and accordingly removed by the plasma generated from the gas including the halogen element.

It is preferable to use F plasma as the halogen plasma. The F plasma refers to plasma generated from the gas including a F element. For example, the F plasma can be generated by supplying a plasma generating device with a single gas or a mixed gas of carbon tetrafluoride (CF₄), methane trifluoride (CHF₃), chlorofluorocarbon (C₂F₆), sulfur hexafluoride (SF₆), nitrogen trifluoride (NF₃), xenon difluoride (XeF₂), fluorine (F₂), and chlorine trifluoride (ClF₃). An expression “oxide film 3 is removed using the F plasma” is intended to indicate that oxide film 3 is removed using a plasma that employs the gas including the F element. In other words, it is intended to indicate that oxide film 3 is processed and accordingly removed by the plasma generated from the gas including the F element.

The H plasma refers to plasma generated from a gas including a H element. The H plasma can be generated by, for example, supplying H₂ gas to a plasma generating device. An expression “oxide film 3 is removed using the H plasma” is intended to indicate that oxide film 3 is etched using the plasma that employs the gas including the H element. In other words, it is intended to indicate that oxide film 3 is processed and accordingly removed by the plasma generated from the gas including the H element.

In the case where the halogen plasma or the H plasma is used in this step S5, it is preferable to remove oxide film 3 at a temperature of not less than 20° C. and not more than 400° C. In this case, damages on SiC substrate 1 can be reduced.

Further, in the case where the halogen plasma or the H plasma is employed in this step S5, it is preferable to remove oxide film 3 at a pressure of not less than 0.1 Pa and not more than 20 Pa. In this case, reactivity between oxide film 3 and the halogen plasma or the H plasma can be increased, thereby facilitating removal of oxide film 3.

It is preferable to thermally decompose oxide film 3 in an atmosphere including no O, at a temperature of not less than 1200° C. and not more than the sublimation temperature of SiC. By heating oxide film 3 at not less than 1200° C. in the atmosphere including no O, oxide film 3 can be readily thermally decomposed. By heating oxide film 3 at not more than the sublimation temperature of SiC, SiC substrate 1 can be restrained from being deteriorated. Further, the thermal decomposition is preferably performed at a reduced pressure in order to facilitate the reaction.

The dry etching is to remove oxide film 3 at a temperature of not less than 1000° C. and not more than the sublimation temperature of SiC, using at least one of hydrogen (H₂) gas and hydrogen chloride (HCl) gas, for example. The hydrogen gas and the hydrogen chloride gas at not less than 1000° C. highly effectively reduce oxide film 3. In the case where the oxide film is made of SiOₓ, the hydrogen gas decomposes SiOₓ into H₂O and SiH_{y}, and the hydrogen chloride gas decomposes SiOₓ into H₂O and SiCl_{z}. With the temperature being not more than the sublimation temperature of SiC, SiC substrate 1 can be restrained from being deteriorated. Further, it is preferable to perform the dry etching at a reduced pressure in order to facilitate reaction.

The wet etching is to remove oxide film 3 using a solution such as HF or NH₄F (ammonium fluoride), for example. In the wet etching, it is preferable to use HF and is more preferable to use diluted HF (DHF) of not less than 1% and not more than 10%. In the case where oxide film 3 is removed using HF, oxide film 3 can be removed by soaking SiC substrate 1 in HF stored in a reaction container, for example.

In the case where wet cleaning employing a liquid phase, such as wet etching, is employed, surface 1a of SiC substrate 1 may be cleaned by pure water after the wet cleaning. The pure water is preferably ultrapure water. The cleaning may be performed by applying a supersonic wave to the pure water. It should be noted that this step may not be performed.

Further, in the case where the wet cleaning is performed, surface 1a of SiC substrate 1 may be dried (drying step). A method of drying is not particularly limited. For example, the drying is performed using a spin dryer or the like. It should be noted that this drying step may not be performed.

By performing this step S5, oxide film 3 having the impurities, particles, and the like incorporated therein in step S2 can be removed, thereby removing impurities, particles, and the like attached to surface 1a of SiC substrate 1 prepared in step S1. Further, a SiC substrate 2 having a surface 2a close to the stoichiometric composition can be formed.

By performing the above-described steps (steps S2 to S5; S10), surface 2a of SiC substrate 2 can be cleaned. It should be noted that steps S2 and S4 may not be performed. By performing cleaning in this way, as shown in FIG. 5, SiC substrate 2 can be obtained which has surface 2a having reduced impurities and particles, for example.

It should be noted that all of or a part of steps S2 to S5 may be performed repeatedly. However, no RCA cleaning is performed during steps S2 to S5. Further, there may be further provided a step of etching surface 2a using a single gas including fluorine atoms or using a mixed gas including the fluorine atoms.

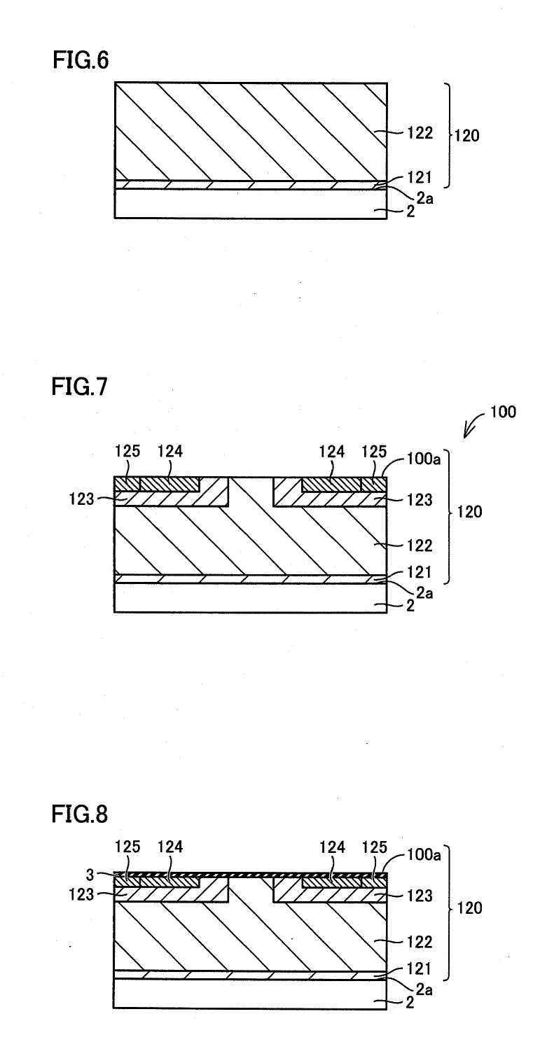

Next, as shown in FIG. 2, FIG. 6, and FIG. 7, an epitaxial layer 120 is formed above surface 2a of SiC substrate 2 by means of the vapor phase epitaxy method, the liquid phase epitaxy method, or the like (step S6). In the present embodiment, for example, epitaxial layer 120 is formed as follows.

Specifically, as shown in FIG. 6, a buffer layer 121 is formed on surface 2a of SiC substrate 2. Buffer layer 121 is made of SiC of n type conductivity, and is an epitaxial layer having a thickness of 0.5 μm, for example. Further, buffer layer 121 contains the conductive impurity at a concentration of, for example, 5×10¹⁷ cm⁻³.

Thereafter, as shown in FIG. 6, a breakdown voltage holding layer 122 is formed on buffer layer 121. As breakdown voltage holding layer 122, a layer made of SiC having n type conductivity is formed by means of the vapor phase epitaxy method, the liquid phase epitaxy method, or the like. Breakdown voltage holding layer 122 has a thickness of, for example, 15 μm. Further, breakdown voltage holding layer 122 includes an impurity of n type conductivity at a concentration of, for example, 5×10¹⁵ cm⁻³.

Next, as shown in FIG. 7, epitaxial layer 120 is subjected to ion implantation (step S7). In the present embodiment, as shown in FIG. 7, p type well regions 123, n⁺ source regions 124, and p⁺ contact regions 125 are formed in the following manner. First, an impurity of p type conductivity is selectively implanted into portions of breakdown voltage holding layer 122, thereby forming well regions 123. Thereafter, an impurity of n type conductivity is selectively implanted into predetermined regions to form source regions 124, and a conductive impurity of p type conductivity is selectively implanted into predetermined regions to form contact regions 125. It should be noted that such selective implantations of the impurities are performed using masks each formed of, for example, an oxide film. The masks are respectively removed after the implantations of the impurities.

After such an implantation step, activation annealing treatment may be performed. For example, the annealing is performed in an argon atmosphere at a heating temperature of 1700° C. for 30 minutes.

By means of these steps, as shown in FIG. 7, an epitaxial wafer 100 including SiC substrate 2 and epitaxial layer 120 formed on SiC substrate 2 can be prepared.

Next, surface 100a of epitaxial wafer 100 is cleaned (steps S2 to S5; S10). The step (step S10) of cleaning surface 100a of epitaxial wafer 100 is basically the same as the step of cleaning surface 1a of SiC substrate 1. It should be noted that in the case where manufacturing device 10 shown in FIG. 1 is used to clean epitaxial wafer 100, epitaxial wafer 100 is transported in connection unit 14 of manufacturing device 10. Hence, connection unit 14 is dimensioned to allow epitaxial wafer 100 or epitaxial wafer 100 placed on a susceptor to be transported therein.

Specifically, as shown in FIG. 2, at least one of an inert gas ion and a hydrogen ion is implanted into surface 100a of epitaxial wafer 100 (step S2).

Next, as shown in FIG. 2 and FIG. 8, oxide film 3 is formed on surface 100a of epitaxial wafer 100 (step S3). This step S3 is the same as step S3 of forming oxide film 3 on surface 1a of SiC substrate 1. However, in the case where surface 100a is damaged by the ion implantation into the epitaxial wafer in step S7, this damaged layer may be oxidized in order to remove the damaged layer. In this case, the oxidation is performed up to more than 10 nm and not more than 100 nm from surface 100a toward SiC substrate 2, for example.

Next, epitaxial wafer 100 is subjected to heat treatment in an atmosphere including an inert gas (step S4). In not only the step (step S3) of forming oxide film 3 but also the step (step S7) of performing ion implantation, carbon may be deposited on surface 100a to result in point defects, but by performing the heat treatment to surface 100a of epitaxial wafer 100 in step S4, carbon on surface 100a can be distributed in epitaxial wafer 100. Accordingly, when removing oxide film 3, a surface close to the stoichiometric composition can be formed.

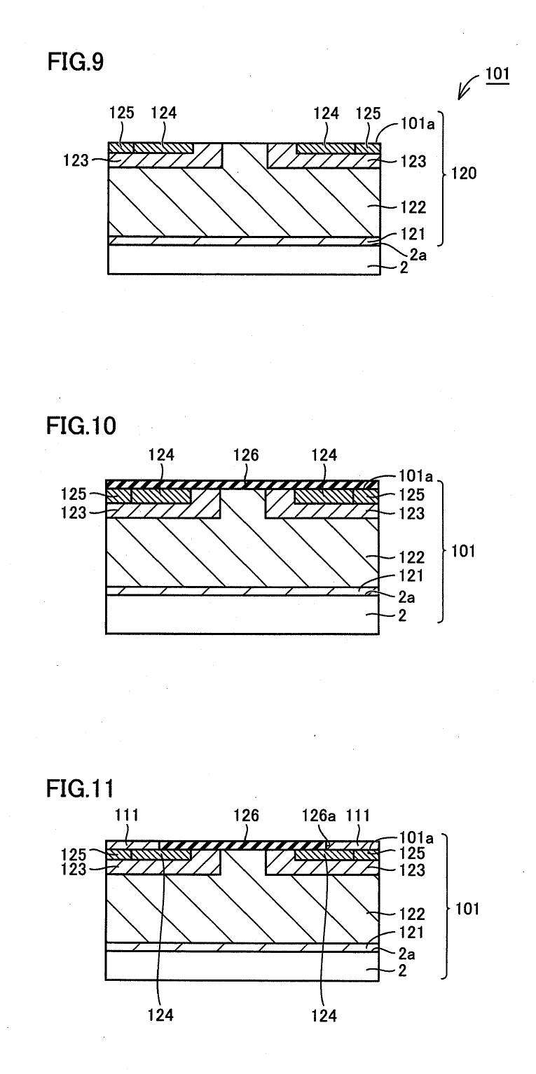

Next, as shown in FIG. 2 and FIG. 9, oxide film 3 formed on surface 100a of epitaxial wafer 100 is removed (step S5).

By performing the above-described steps (steps S2 to S5; S10), impurities, particles, and the like attached to surface 100a of epitaxial wafer 100 can be removed while forming a surface close to the stoichiometric composition. In this way, epitaxial wafer 101 can be obtained which has reduced impurities and particles and has surface 101a close to the stoichiometric composition as shown in FIG. 9, for example.

Next, a gate oxide film 126, which is an oxide film to constitute the SiC semiconductor device, is formed on cleaned surface 101a of epitaxial wafer 101 (step S8). Specifically, as shown in FIG. 10, gate oxide film 126 is formed on surface 101a to cover breakdown voltage holding layer 122, well regions 123, source regions 124, and contact regions 125. Oxide film 126 can be formed through, for example, thermal oxidation (dry oxidation). The thermal oxidation is performed by, for example, heating it to a high temperature in an atmosphere including oxygen elements such as O₂, O₃, N₂O, and the like. Conditions for the thermal oxidation are, for example, as follows: the heating temperature is 1200° C. and the heating time is 30 minutes. It should be noted that gate oxide film 126 may be formed by not only the thermal oxidation but also, for example, the CVD method, the sputtering method, or the like. Gate oxide film 126 is formed of a silicon oxide film having a thickness of, for example, 50 nm.

When fabricating the SiC semiconductor device by thus forming gate oxide film 126, which constitutes the SiC semiconductor device, on surface 101a having reduced impurities, particles, and the like, gate oxide film 126 can be improved in its properties while reducing impurities, particles, and the like at gate oxide film 126 and an interface between surface 101a and gate oxide film 126. Accordingly, breakdown voltage of the SiC semiconductor device can be improved when applying a reverse voltage, while improving stability and long-term reliability of operations when applying a forward voltage.

It should be noted that between the step (step S5) of cleaning surface 101a of epitaxial wafer 101 and the step (step S8) of forming the oxide film to constitute the SiC semiconductor device, epitaxial wafer 101 is preferably in an atmosphere isolated from the ambient air. In other words, the manufacturing device shown in FIG. 1 preferably includes a second connection unit capable of isolation from the ambient air and disposed between removing unit 12 and the second forming unit, which forms the oxide film to constitute the SiC semiconductor device. In this case, epitaxial wafer 100 having surface 100a cleaned is transported in the second connection unit isolated from the ambient air. In this way, after removing oxide film 3, impurities in the ambient air can be restrained from attaching to surface 101a of epitaxial wafer 101.

Thereafter, nitrogen annealing (step S9) is performed. Specifically, annealing treatment is performed in a nitrogen monoxide (NO) atmosphere. Conditions for this treatment are, for example, as follows: the heating temperature is 1100° C. and the heating time is 120 minutes. As a result, nitrogen atoms can be introduced into a vicinity of an interface between gate oxide film 126 and each of breakdown voltage holding layer 122, well regions 123, source region 124, and contact regions 125.

It should be noted that after the nitrogen annealing step (step S9) using nitrogen monoxide, additional annealing treatment may be performed using argon gas, which is an inert gas (step S11). Conditions for this treatment are, for example, as follows: the heating temperature is 1100° C. and the heating time is 60 minutes.

Further, after the nitrogen annealing step (step S9), surface cleaning may be performed such as organic cleaning, acid cleaning, or RCA cleaning.

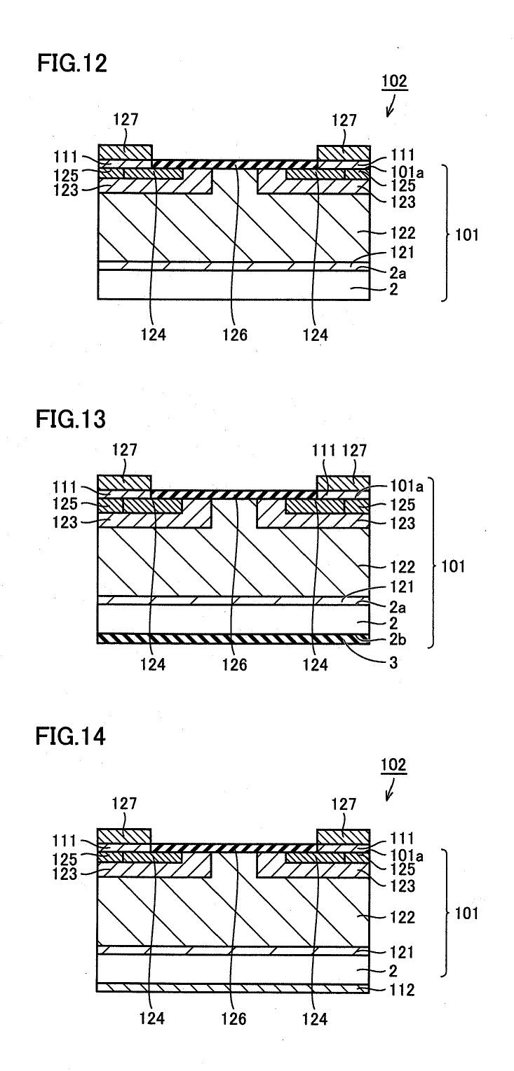

Next, as shown in FIG. 2, FIG. 11, and FIG. 12, source electrodes 111, 127 are formed (step S12). Specifically, a resist film having a pattern is formed on gate oxide film 126 by means of the photolithography method. Using the resist film as a mask, portions above source regions 124 and contact regions 125 in gate oxide film 126 are removed by etching. In this way, openings 126a are formed in gate oxide film 126. By means of a deposition method for example, in each of openings 126a, a conductive film is formed in contact with each of source regions 124 and contact regions 125. Then, the resist film is removed, thus removing (lifting off) the conductive film's portions located on the resist film. This conductive film may be a metal film, for example, may be made of nickel (Ni). As a result of the lift-off, source electrodes 111 are formed.

On this occasion, heat treatment for alloying is preferably performed. For example, the heat treatment is performed in an atmosphere of argon (Ar) gas, which is an inert gas, at a heating temperature of 950° C. for two minutes.

Thereafter, as shown in FIG. 12, upper source electrodes 127 are formed on source electrodes 111 by means of, for example, the deposition method.

Next, backside surface 2b of SiC substrate 2 is back-grinded (BG) to smooth backside surface 2b. Backside surface 2b of SiC substrate 2 is cleaned (steps S2 to S5; S10). The step (step S10) of cleaning backside surface 2b of SiC substrate 2 is basically the same as the step of cleaning surface 1a of SiC substrate 1. It should be noted that in the case where manufacturing device 10 shown in FIG. 1 is used to clean backside surface 2b of SiC substrate 2, epitaxial wafer 101 having source electrodes 111, 127 formed thereon is transported in connection unit 14 of manufacturing device 10. Hence, connection unit 14 is dimensioned to allow for transportation of epitaxial wafer 100 having source electrodes 111, 127 formed thereon or epitaxial wafer 100 placed on a susceptor.

Specifically, as shown in FIG. 2, at least one of an inert gas ion and a hydrogen ion is implanted into backside surface 2b of SiC substrate 2 (step S2). Then, as shown in FIG. 2 and FIG. 13, oxide film 3 is formed on backside surface 2b of SiC substrate 2 (step S3). Next, as shown in FIG. 2, backside surface 2b of SiC substrate 2 is subjected to heat treatment in an atmosphere including an inert gas (step S4). Thereafter, as shown in FIG. 2, oxide film 3 formed on backside surface 2b of SiC substrate 2 is removed (step S5).

By performing the above-described steps (steps S2 to S5; S10), impurities, particles, and the like attached to backside surface 2b of SiC substrate 2 can be removed. Further, a damaged layer resulting from the back grinding in step S3 of forming oxide film 3 can be also oxidized. Hence, the damaged layer can be removed by means of back grinding. Further, a surface close to the stoichiometric composition can be obtained.

Next, as shown in FIG. 2 and FIG. 14, a drain electrode 112 is formed on the backside surface of SiC substrate 2 (step S13). A method of forming drain electrode 112 is not particularly limited, but drain electrode 112 can be formed by, for example, the deposition method.

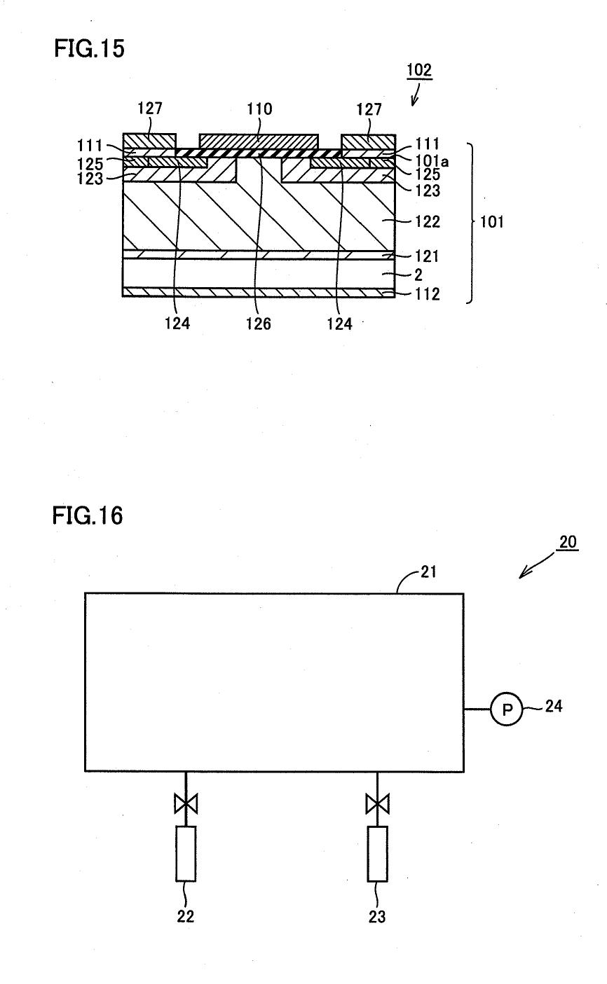

Next, as shown in FIG. 2 and FIG. 15, gate electrode 110 is formed (step S14). A method of forming gate electrode 110 is not particularly limited, but gate electrode 110 can be formed as follows, for example. That is, a resist film having an opening pattern in conformity with regions on gate oxide film 126 is formed in advance. A conductor film to constitute the gate electrode is formed to cover the entire surface of the resist film. Then, the resist film is removed, thereby removing (lifting off) portions of the conductor film other than its portion to be the gate electrode. As a result, as shown in FIG. 15, gate electrode 110 can be formed on gate oxide film 126.

By performing the above-described steps (steps S1 to S14), MOSFET 102 serving as the SiC semiconductor device in FIG. 15 can be manufactured.

Here, it has been illustrated that in the present embodiment, the SiC semiconductors' surfaces cleaned in the steps (steps S2 to S5; S10) of cleaning are surface 1a of SiC substrate 1 before forming epitaxial layer 120, ion-implanted surface 100a of epitaxial wafer 100, and backside surface 2b of SiC substrate 2 opposite to its surface on which the epitaxial layer is formed in epitaxial wafer 100. However, the SiC semiconductors' surfaces cleaned in the step of cleaning are not limited to the above. For example, surface 100a of epitaxial wafer 100 in FIG. 7 before ion implantation may be cleaned. Further, only one of the above may be cleaned.

Further, a configuration can be employed in which conductivity types are opposite to those in the present embodiment. Namely, a configuration can be employed in which p type and n type are replaced with each other.

Further, although SiC substrate 2 is employed to fabricate MOSFET 102, the material of the substrate is not limited to SiC. MOSFET 102 may be fabricated using a crystal of other material. Further, SiC substrate 2 may be omitted.

As described above, the method for manufacturing MOSFET 102 serving as one exemplary SiC semiconductor device in the present embodiment includes: the step (step S3) of forming an oxide film on a surface of a SiC semiconductor; and the step (step S5) of removing the oxide film, ozone gas being used in the step (step S3) of forming the oxide film.

According to the method for manufacturing the SiC semiconductor device in the present embodiment, oxide film 3 is formed using the ozone gas. The ozone gas has high oxidizing energy (degree of activity), and therefore readily allows oxide film 3 to be formed on the surface of the SiC semiconductor, which is a highly stable compound. In this way, oxide film 3 can be readily formed to incorporate impurities, particles, and the like attached to the surface thereof. By removing this oxide film 3, the impurities, the particles, and the like incorporated therein can be removed. Accordingly, a cleaning effect can be improved as compared with that of the RCA cleaning with a low degree of activity.

If the RCA cleaning is performed, a massive amount of chemical solution is used in a batch process and a problem arises in handling a waste liquid also in the spin cleaning. In contrast, in the step (step S3) of forming the oxide film in the present embodiment, oxide film 3 is formed in the dry atmosphere. Hence, no chemical solution needs to be used. Accordingly, the problems associated with a chemical solution involved in cleaning can be reduced. It should be noted that the term “dry atmosphere” is intended to indicate that oxide film 3 is formed in a vapor phase, and may include an unintended liquid phase component.

Further, by performing the step (step S3) of forming the oxide film in the present embodiment and the step (step S5) of removing the oxide film, C can be removed by removing CO or CO₂ in the carbon rich surface, thereby forming a surface in which Si and C are close to the stoichiometric composition. Accordingly, the properties of the surface to be cleaned can be improved, which leads to improved properties of the SiC semiconductor device, which will have this surface.

Manufacturing device 10 for the SiC semiconductor in the embodiment of the present invention includes: a forming unit 11 for forming an oxide film 3 on a surface of a SiC semiconductor; a removing unit 12 for removing oxide film 3 using ozone gas; and a connection unit 14 connecting forming unit 11 and removing unit 12 to each other to allow the SiC semiconductor to be transported therein, connection unit 14 having a region in which the SiC semiconductor is transported and which is capable of being isolated from ambient air.

According to manufacturing device 10 for the SiC semiconductor device in the present embodiment, the SiC semiconductor can be restrained from being exposed to the ambient air while forming oxide film 3 on the SiC semiconductor by forming unit 11 and thereafter removing oxide film 3 by removing unit 12. In this way, impurities in the ambient air can be restrained from attaching to the surface of the SiC semiconductor again. Further, because the oxide film is formed using the ozone gas having a high degree of activity, the oxide film can be readily formed. Accordingly, the cleaning effect can be improved as compared with that of the RCA cleaning with a low degree of activity.

Further, in forming unit 11, oxide film 3 can be formed without using a chemical solution. Accordingly, the problems associated with a chemical solution involved in cleaning can be reduced.

It should be noted that although the method for manufacturing the vertical type MOSFET as the SiC semiconductor device has been illustrated in the present embodiment, the semiconductor device is not particularly limited. For example, the present invention can be applied to semiconductor devices each having an insulated gate type electric field effect unit or to general SiC semiconductor devices. Examples of the semiconductor device having the insulated gate type electric field effect unit include: a lateral type MOSFET and an IGBT (Insulated Gate Bipolar Transistor). An example of the general SiC semiconductor devices is a JFET (Junction Field-Effect Transistor).

### Second Embodiment

FIG. 16 is a schematic view of a manufacturing device for a SiC semiconductor device in a second embodiment of the present invention. Referring to FIG. 16, the following describes the manufacturing device for the SiC semiconductor device in the present embodiment.

As shown in FIG. 16, manufacturing device 20 in the present embodiment includes a chamber 21, a first gas supplying unit 22, a second gas supplying unit 23, and a vacuum pump 24. Each of first gas supplying unit 22, second gas supplying unit 23, and vacuum pump 24 is connected to chamber 21.

Chamber 21 accommodates a SiC semiconductor therein. First gas supplying unit 22 supplies a gas to chamber 21 to form an oxide film on a surface of the SiC semiconductor. First gas supplying unit 22 supplies a gas including ozone gas. Second gas supplying unit 23 supplies a gas to remove oxide film 3 formed on the SiC semiconductor. Second gas supplying unit 23 supplies a gas including, for example, halogen or H. Hence, second gas supplying unit 23 can generate halogen plasma or H plasma in chamber 21. In this way, oxide film 3 formed on the surface of the SiC semiconductor can be removed.

Vacuum pump 24 vacuums the inside of chamber 21. Thus, oxide film 3 can be removed by vacuuming the inside of chamber 21 after forming oxide film 3 on the surface of the SiC semiconductor using the ozone gas. It should be noted that vacuum pump 24 may not be provided.

Further, manufacturing device 20 may include a third gas supplying unit (not shown). The third gas supplying unit supplies an inert gas to provide heat treatment to the SiC semiconductor in chamber 21.

It should be noted that manufacturing device 20 shown in FIG. 16 may include various elements other than those described above, but for ease of description, these elements are not shown in the figures and are not explained.

The method for manufacturing the SiC semiconductor device in the present embodiment is configured basically the same as that of the first embodiment, but is different therefrom in that manufacturing device 20 of the present embodiment is used. It should be noted that in the present embodiment, the step (step S5) of removing oxide film 3 is performed in a dry atmosphere.

As described above, manufacturing device 20 for the SiC semiconductor device in the present embodiment includes: a forming unit for forming an oxide film 3 on a surface of a SiC semiconductor using ozone gas; and a removing unit for removing oxide film 3, the forming unit and the removing unit being the same component (chamber 21).

According to manufacturing device 20 for the SiC semiconductor device in the present embodiment, the SiC semiconductor does not need to be transported while forming oxide film 3 on the SiC semiconductor by the forming unit and thereafter removing oxide film 3 by the removing unit. Hence, the SiC semiconductor is not exposed to the ambient air. In other words, between step S3 of forming oxide film 3 and step S5 of removing oxide film 3, the SiC semiconductor is in an atmosphere isolated from the ambient air. In this way, impurities in the ambient air can be restrained from attaching to the surface of the SiC semiconductor again during cleaning of the SiC semiconductor. Further, because oxide film 3 is formed using ozone gas having a high degree of activity, oxide film 3 can be readily formed on the surface of the SiC semiconductor, which is a stable compound. Accordingly, the cleaning effect can be improved as compared with that of the RCA cleaning with a low degree of activity.

Further, the formation and removal of oxide film 3 can be carried out in a dry atmosphere without using a chemical solution. Accordingly, the problems associated with a chemical solution involved in cleaning can be further reduced.

### EXAMPLE

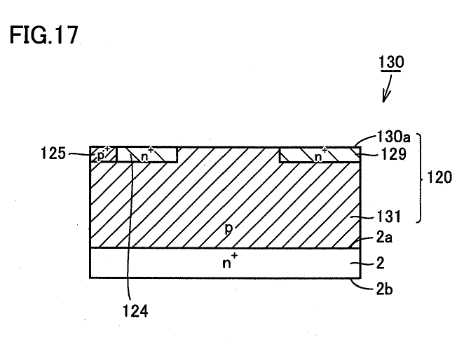

Examined in the present example was an effect of forming an oxide film using ozone gas when cleaning an epitaxial wafer 130 serving as a SiC semiconductor and shown in FIG. 17. It should be noted that FIG. 17 is a cross sectional view schematically showing epitaxial wafer 130 to be cleaned in the present example.

### Example 1

First, as SiC substrate 2, a 4H—SiC substrate having a surface 2a was prepared (step S1).

Next, as a layer constituting an epitaxial layer 120, a p type SiC layer 131 was grown by means of the CVD method to have a thickness of 10 μm and have an impurity concentration of 1×10¹⁶ cm⁻³ (step S6).

Next, using SiO₂ as a mask, a source region 124 and a drain region 129 were formed to have an impurity concentration of 1×10¹⁹ cm⁻³ with phosphorus (P) being employed as an n type impurity. Further, with aluminum (Al) being employed as a p type impurity, contact region 125 was formed to have an impurity concentration of 1×10¹⁹ cm⁻³ (step S7). It should be noted that after each of the ion implantations, the mask was removed.

Next, activation annealing treatment was performed. The activation annealing treatment was performed under conditions that Ar gas was used as an atmospheric gas, and heating temperature was set at 1700° C. to 1800° C., and heating time was set at 30 minutes.

In this way, epitaxial wafer 130 having a surface 130a was prepared. Next, using manufacturing device 10 shown in FIG. 1, surface 130a of epitaxial wafer 130 was cleaned (step S10).

Specifically, using ozone gas, an oxide film was formed (step S3). In this step S3, epitaxial wafer 130 was heated to 400° C. at 5 Pa in an atmosphere including argon. In this way, it was confirmed that an oxide film having a thickness of 1 nm could be formed on surface 130a of epitaxial wafer 130.

Next, epitaxial wafer 130 was transported to heat treatment unit 13 via connection unit 14 and was subjected to heat treatment in an atmosphere including an inert gas (step S4). The heat treatment was performed under conditions that argon was used as the inert gas and epitaxial wafer 130 was heated at 1300° C. or greater.

Next, epitaxial wafer 130 was transported to removing unit 12 via connection unit 14, and the oxide film formed on surface 130a of epitaxial wafer 130 was removed (step S5). In this step S5, the removal was done using hydrofluoric acid having a concentration of 10%. In this way, it was confirmed that the oxide film formed in step S3 could be removed.

With the above-described steps (steps S3 to S5; S10), surface 130a of epitaxial wafer 130 was cleaned. Impurities and particles on the surface of epitaxial wafer 130 of Example 1 after the cleaning are reduced as compared with those on surface 130a before the cleaning. Further, the surface of epitaxial wafer 130 of Example 1 after the cleaning was a SiC surface close to the stoichiometric composition.

### Example 2

In Example 2, first, epitaxial wafer 130 shown in FIG. 17 and similar to that of Example 1 was prepared (steps S1, S6, S7).

Next, backside surface 2b of SiC substrate 2 was back-grinded. Next, an oxide film was formed on this backside surface 2b (step S3). Thereafter, heat treatment was performed (step S4). Next, the oxide film was removed (step S5). Conditions in steps S3 to S5 were the same as those in Example 1.

With the above-described steps (steps S3 to S5), backside surface 2b of SiC substrate 2 of epitaxial wafer 130 was cleaned. Impurities and particles on the backside surface of SiC substrate 2 of Example 2 after the cleaning were reduced as compared with those on backside surface 2b before the cleaning. Further, the backside surface of SiC substrate 2 of Example 2 after the cleaning was a SiC surface close to the stoichiometric composition.

### Example 3

Example 3 was basically the same as Example 1, but was different therefrom in that it included the step (step S2) of implanting at least one of an inert gas ion and a hydrogen ion into surface 130a of epitaxial wafer 130 before the step (step S3) of forming the oxide film. Specifically, as the inert gas ion, the hydrogen ion was used and was implanted into surface 130a entirely. It was confirmed that by implanting the inert gas ion, the oxide film can be formed more readily with surface 130a being oxidized using the ozone gas in step S3.

Heretofore, the embodiments and examples of the present invention have been illustrated, but it has been initially expected to appropriately combine features of the embodiments and examples. The embodiments and examples disclosed herein are illustrative and non-restrictive in any respect. The scope of the present invention is defined by the terms of the claims, rather than the embodiments and examples described above, and is intended to include any modifications within the scope and meaning equivalent to the terms of the claims.

### REFERENCE SIGNS LIST

1, 2: SiC substrate; 1a, 2a, 100a, 101a, 130a: surface; 2b: backside surface; 3: oxide film; 10, 20: manufacturing device; 11: forming unit; 12: removing unit; 13: heat treatment unit; 14: connection unit; 21: chamber; 22: first gas supplying unit; 23: second gas supplying unit; 24: vacuum pump; 100, 101, 130: epitaxial wafer; 110: gate electrode; 111, 127: source electrode; 112: drain electrode; 120: epitaxial layer; 121: buffer layer; 122: breakdown voltage holding layer; 123: well region; 124: source region; 125: contact region; 129: drain region; 131: p type SiC layer.

1. A method for manufacturing a silicon carbide semiconductor device, comprising the steps of:
forming an oxide film on a surface of a silicon carbide semiconductor; and
removing said oxide film,
in the step of forming said oxide film, ozone gas being used.

2. The method for manufacturing the silicon carbide semiconductor device according to claim 1, wherein in the step of removing said oxide film, halogen plasma or hydrogen plasma is used.

3. The method for manufacturing the silicon carbide semiconductor device according to claim 2, wherein in the step of removing said oxide film, fluorine plasma is used as said halogen plasma.

4. The method for manufacturing the silicon carbide semiconductor device according to claim 2, wherein the step of removing said oxide film is performed at a temperature of not less than 20° C. and not more than 400° C.

5. The method for manufacturing the silicon carbide semiconductor device according to claim 2, wherein the step of removing said oxide film is performed at a pressure of not less than 0.1 Pa and not more than 20 Pa.

6. The method for manufacturing the silicon carbide semiconductor device according to claim 1, wherein in the step of removing said oxide film, hydrogen fluoride is used.

7. The method for manufacturing the silicon carbide semiconductor device according to claim 1, further comprising the step of performing, between the step of forming said oxide film and the step of removing said oxide film, heat treatment to said silicon carbide semiconductor in an atmosphere including an inert gas.

8. The method for manufacturing the silicon carbide semiconductor device according to claim 1, further comprising the step of implanting, prior to the step of forming said oxide film, at least one of an inert gas ion and a hydrogen ion into said surface of said silicon carbide semiconductor.

9. The method for manufacturing the silicon carbide semiconductor device according to claim 1, wherein in the step of forming said oxide film, said silicon carbide semiconductor is heated to not less than 20° C. and not more than 600° C.

10. The method for manufacturing the silicon carbide semiconductor device according to claim 1, wherein the step of forming said oxide film is performed at a pressure of not less than 0.1 Pa and not more than 50 Pa.

11. The method for manufacturing the silicon carbide semiconductor device according to claim 1, wherein the step of forming said oxide film is performed in an atmosphere including at least one selected from a group consisting of nitrogen, argon, helium, carbon dioxide, and carbon monoxide.

12. A device for manufacturing a silicon carbide semiconductor device, comprising:
a forming unit for forming an oxide film on a surface of a silicon carbide semiconductor;
a removing unit for removing said oxide film using ozone gas; and
a connection unit connecting said forming unit and said removing unit to each other to allow said silicon carbide semiconductor to be transported therein,
said connection unit having a region in which said silicon carbide semiconductor is transported and which is capable of being isolated from ambient air.

13. A device for manufacturing a silicon carbide semiconductor device, comprising:
a forming unit for forming an oxide film on a surface of a silicon carbide semiconductor using ozone gas; and
a removing unit for removing said oxide film, said forming unit and said removing unit being the same component.
